(19) United States
(12) Patent Application Publication
(10) Pub. No.: US 2007/0246789 A1
(43) Pub. Date: Oct. 25, 2007

(54) THERMIONIC FLAT ELECTRON EMITTER

(76) Inventors: Joerg Freudenberger, Eckental (DE); Peter Schardt, Aisch (DE); Frank Sprenger, Erlangen (DE)

Correspondence Address: SCHIFF HARDIN, LLP;PATENT DEPARTMENT, 6600 SEARS TOWER, CHICAGO, IL, 60606-6473, US

(21) Appl. No.: 11/737,192

(22) Filed: Apr. 19, 2007

(30) Foreign Application Priority Data
Apr. 21, 2006 (DE) 10 2006 018 633.8

(51) Int. Cl. H01L 31/00

(52) U.S. Cl. 257/448

(57) ABSTRACT

A thermionic flat electron emitter has an emitter arrangement with an emitter plate having slits therein that produce serpentine current paths. The emitter arrangement has a structure that, in operation, causes the electron density of the emitted electrons to be lower in the central region of the emitter plate than in a region adjoining the central region.

### BACKGROUND OF THE INVENTION

1. Field of the Invention

The invention concerns a thermionic flat electron emitter that has an emitter arrangement with an emitter plate. Slits for generation of serpentine current paths are incorporated into the emitter plate.

2. Description of the Prior Art

The emitter plate of such a surface emitter is provided with heating current connections. A heating current is conducted through the emitter plate by means of these heating current connections. The emitter plate (composed of a high temperature-resistant metal such as tungsten) is thereby heated to a very high temperature, approximately on the order of 2000° C. Electrons are emitted from the emitter plate due to this high temperature.

When the surface emitter is installed in an x-ray tube, the electrons emitted from the emitter plate are accelerated toward an anode by a high voltage. The emitted electrons are focused by a focusing system in the path from the emitter plate to the anode. Upon impact of the electrons in a focal spot on the anode (which is likewise produced from a high temperature-resistant material such as tungsten), x-ray radiation is created due to the deceleration of the electrons in the anode material. The goal of the focusing is to cause the electrons to strike the anode in an optimally narrow region and with an optimally uniform electron distribution density. A high image quality can thereby be achieved, in particular given use of the x-ray tube in high-resolution imaging such as, for example, in medical diagnostic apparatuses.

The electron density distribution can be influenced by the arrangement of the slits incorporated into the emitter plate.

A rectangular emitter plate with two opposite heating current connections is described in DE OS 27 27 907, the rectangular emitter plate being provided with slits such that a continuous current path results between the two heating current connections.

The emitter plate described in U.S. Pat. No. 6,115,453 has a circular outer contour with two opposing heating current connections. Here as well slits are introduced into the emitter plate such that a continuous current path results between the two current connections. The current path is serpentine.

An emitter plate with a circular outer contour is known from DE 100 29 253 C1, into which a number of slits, not connected with one another, is introduced. The current path between the two heating current connections is also provided in this manner.

In all three described variants of a slit structure of the emitter plate, the electrical resistance of the emitter plate can be configured by the width of the current path (i.e. via the spacing of two adjacent slits) as well as by the plate thickness. The width of the current path and the thickness of the composite material are also variable over the surface of the emitter plate. The temperature of the emitter plate resulting from the heating current thus can be adjusted in a spatially-dependent manner. The electron density distribution of the electrons emitted by the emitter plate corresponds in turn with this temperature distribution. In DE 100 16 125 A1 it is explicitly specified that temperature gradients on the surface of the emitter plate can be compensated through a variation of the current path width for generation of a homogeneous temperature distribution.

Auxiliary measures for homogenization of the electron density distribution of the emitter plate are also known. From DE 19 914 739 C1 it is known to separately heat the heating current connections. A dissipation of heat that occurs at the heating current connections is thereby compensated.

A temperature gradient on the emitter plate that leads to a mechanical deformation of this emitter plate, and thus to an alteration of the electron irradiation characteristic, is compensated by mechanical compensation elements in DE 100 12 203 C1.

### SUMMARY OF THE INVENTION

An object of the present invention is based on the object to specify a surface emitter that is particularly suitable for use in an x-ray tube for high-resolution imaging.

This object is achieved according to the invention by an emitter arrangement having a structure that, in operation, causes the electron density of the emitted electrons to be lower in the central region of the emitter plate than in a region adjoining the central region. “Electron density,” as used herein is the number of electrons emitted per time and area unit. A broadening of the electron beam due to the repulsion of the electrons among one another is hereby countered, particularly given a very high electron density. Due to the very high speed and the very high momentum of the electrons, this broadening of the electron beam can only be partially compensated by focusing elements. A reduction of the electron density in the central region of the emitter plate leads to the situation that the expansion of the electron beam is lower in comparison to a conventional emitter plate. A field strength of smaller size thus can be achieved at the anode location with the same focusing device. Improvements in the image quality thus can be achieved, particularly in high-resolution imaging by means of x-ray radiation. In the medical field, a higher image quality means that tissue structures can be better resolved and a medical diagnosis can thus be generated more precisely and exactly.

A lower electron density of the emitted electrons of the emitter plate is achieved in several embodiments wherein the aforementioned structure is the arrangement of the slits in the emitter plate. The resistance of the emitter plate (which resistance counteracts the heating current) is variable by varying the current path width, i.e. of the interval between two adjacent slits. A smaller interval between two adjacent slits, meaning a narrow current path, means that the declining heating voltage is lower at the current path and a lower temperature is thereby achieved locally. For example, the greater interval of the slits in the central region of the emitter plate can be larger than in the region adjoining this central region. The average temperature (and therewith also the average emitted electron density) in the central region is thus lower than in the region adjoining this central region. Since only the arrangement of the slits on the emitter plate is altered, no adjustment with regard to the production method is necessary for the introduction of the slits. Proven production methods (such as, for example, an electrical discharge (spark erosion) separation process, laser cutting or a similar suitable method) can be used to.

In an embodiment, the central region of the emitter plate is connected with the adjoining region only by a single connection web. Upon application of a heating current between the two heating current connections, no heating voltage drop occurs in the central region of the emitter plate. The central region is therefore essentially heated only with heat conduction through the single connection web. Thus no electrons or almost no electrons, are emitted by the central region. This has the advantage of allowing a design for the arrangement of the slits that was already created for an emitter plate emitting over its entire surface to essentially still be used. The arrangement of the slits in a region adjoining the central region is simply adopted; by contrast, for simplicity the central region is preferably free of slits over its entire surface, since it contributes nothing to the emission. Costs can thus be saved in the design of the emitter plate.

In a further variant, the central region of the emitter plate is connected with the adjoining region of the emitter plate by two opposing connection webs. The two connection webs are arranged such that they are at the same potential in operation, namely given application of a heating current. This variant exhibits the same advantages as the variant with the single connection web, but since the central region of the emitter plate is now retained via two connection webs, it is connected more mechanically stably with the adjoining region in comparison to the solution with the single connection web. Moreover, if the width of the connection webs is selected sufficiently large, thus can cause a lower heating current to flow between the two connection webs and a heating voltage drop thus occurs at the central region. The central region thus emits electrons of a lower electron density. The electron density distribution of the emitter plate thus can be compensated so a particularly homogeneous electron density can be achieved at the focal spot of the anode by means of the focusing elements.

In another embodiment, the central region of the emitter plate is connected with the adjoining region by two connection webs that are offset from to one another by a non-180° angle. In operation a potential difference thus exists between the two connection webs given an operating voltage applied to the emitter plate. The magnitude of the potential difference can be set by the selection of the angle between the two connection webs. A heating current in the central region of the emitter plate flows dependent on the magnitude of this potential difference, such that the electron density distribution of the electrons emitted from this central region can varied more distinctly using the declining heating voltage at the central region (and the temperature of this central region resulting from this) than in the embodiment with the two connection webs at the same potential. The electron density distribution of the electrons emitted at the emitter plate therefore can be optimized to the effect so that a homogeneous electron density distribution occurs at the focal spot of the anode.

The emitter plate is advantageously connected to at least two circuits such that, in operation, a lower current density exists in the central region than in the adjoining region. Since the lower current density is achieved in the central region by a combination of the arrangement of the slits and the heating current connections, the central region can essentially be free of slits over the entire surface. A high mechanical stability of the emitter plate thereby results. An advantage that makes the increased effort of the connection to at least two circuits worthwhile is the fact that the temperature gradient on the emitter plate, and thus the electron density distribution of the electrons emitted by the emitter plate, can be provided in a continuously variable manner dependent on the arrangement of the slits and the arrangement of the current connections.

In a version of this embodiment, the emitter plate is connected to two circuits with connections that are respectively offset from one another in pairs by 90°.

All versions of emitter plates in which fewer or no electrons are emitted in the central region have a further advantage in common. Since the very high temperature prevailing in the focal spot at the anode leads to a permanent ionization of anode material, and these ions are accelerated toward the surface emitter of the cathode due to its positive charge, these ions kick out material upon impact on the emitter plate. The emitter plate is slowly eroded in this manner. These ions now preferably strike in the middle region of the emitter plate, but this region in the inventive surface emitter is of only lesser or even no importance for the generation of the electron density distribution. Since the central region of the inventive surface emitter is (considered from the electrical standpoint) largely inactivated, damages to this region lead to no change or only to a very slight change of the electron density distribution. Such a surface emitter thus remains functional longer relative to conventional surface emitters. It must therefore be exchanged less often, which leads to a cost savings.

In a further embodiment, the emitter arrangement has, as the aforementioned structure, a diaphragm plate that is located before the central region. A conventional surface emitter can be used in this embodiment. The electrons emitted from the central region of this surface emitter are accelerated toward the diaphragm and strike on this diaphragm. They are therefore not accelerated toward the anode. The electron density distribution of a conventional emitter plate with a diaphragm arranged before the central region of this emitter plate therefore results in an electron density distribution that is likewise less in the central region than in the adjoining region. No additional costs arise in the design of the surface emitter due to the use of a conventional surface emitter. The diaphragm plate additionally protects the surface emitter from damage due to ions accelerated from the anode toward the cathode, such that the surface emitter must be changed significantly less often relative to an arrangement without diaphragm plate.

X-ray tubes known as rotary piston tubes (radiators) are preferably used in high-resolution imaging by means of x-ray radiation, particularly in medical technology. Since the entire tube rotates in a rotary piston radiator, a rotationally symmetrical embodiment of all focusing elements, that are also moving, is necessary. An optimal electron density distribution at the anode location can be achieved by the electron beam to be focused also exhibiting a rotationally symmetrical shape. This is achieved by both the central region of the surface emitter and the emitter plate itself exhibiting a rotationally symmetrical (in particular an essentially circular) outer contour. If a diaphragm plate is used, this preferably also exhibits a rotationally symmetrical (preferably a circular) outer contour.

### DESCRIPTION OF THE DRAWINGS

FIG. 1 shows a conventional surface emitter with a focusing element in a plan view and in section.

FIG. 2 shows a surface emitter in accordance with the invention with a focusing element in a plan view and in section.

FIG. 3 shows, in plan view, an emitter plate in accordance with the invention having a central region connected via a connection web with the adjoining region.

FIG. 4 shows in plan view, an emitter plate in accordance with the invention having a central region connected with the adjoining region via two connection webs at the same potential.

FIG. 5 shows in plan view, an emitter plate in accordance with the present invention having a central region connected with the adjoining region via two connection webs at different potentials.

FIG. 6 shows in plan view, an emitter plate in accordance with the invention designed for connection to two circuits.

FIG. 7 schematically illustrates a surface emitter with a diaphragm plate arranged before the central region of the emitter plate in accordance with the invention, in plan view and in section.

### DESCRIPTION OF THE PREFERRED EMBODIMENTS

FIG. 1 shows a conventional surface emitter 1 in a plan view and in section. The plan view shows the emitter plate 2 with a central region 3 (dark hatching) and the region 4 (light hatching) adjoining this central region 3. The emitter plate 2 is surrounded by an annular focusing element 5. The vertical dashed line proceeding through the center point of the emitter plate 2 symbolizes the section plane for the section drawing.

The heater 6 that heats the emitter plate 2 by means of a heating current 7 is schematically shown in the section drawing. In a conventionally-designed surface emitter 1 the central region 3 emits an electron beam of high density 8′. This is shown dark in order to indicate the high electron density. The region 4 adjoining this central region 3 emits an electron beam of medium density 8. The focusing element 5 arranged around the emitter plate exhibits the shape of a flat cylinder open at one side, with the emitter plate 2 arranged on the cylinder base. The focusing effect of the focusing element 5 is indicated by a convergence of the electron beams of high density 8′ and medium density 8.

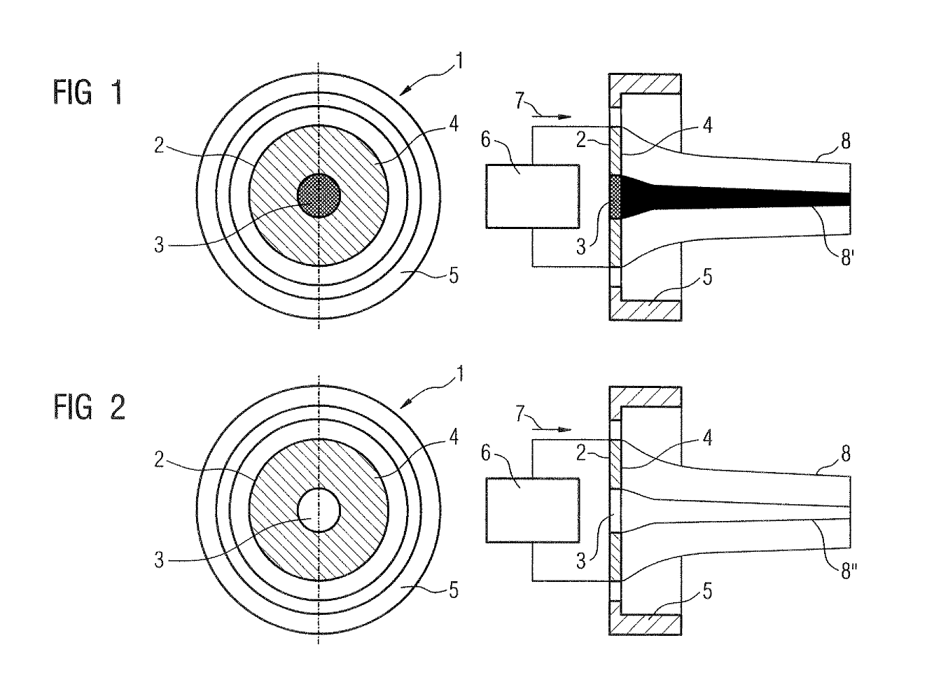

In plan view and in section, FIG. 2 shows an inventive surface emitter 1. FIG. 2 corresponds to FIG. 1, but with the important difference that the central region 3 in the emitter plate 2 of the inventive surface emitter 1 emits an electron beam of lower density 8″. This is indicated in FIG. 2 by both the region 3 and the electron beam of lower density 8″ being shown without hatching. In the section view it can be seen that focusing of the electron beam 8, 8″ is achieved by means of the focusing element 5. Since no electrons or only few electrons are emitted from the central region 3 at the starting point of the electron beam, a lesser beam expansion due to mutually repelling electrons ensues than in the case of FIG. 1, where an electron beam of high density 8 is emitted in the central region 3. Given a predetermined distance between the surface emitter 1 and an anode (not shown), an improved focusing thus can be achieved while retaining the focusing element 5 with identical focusing parameters.

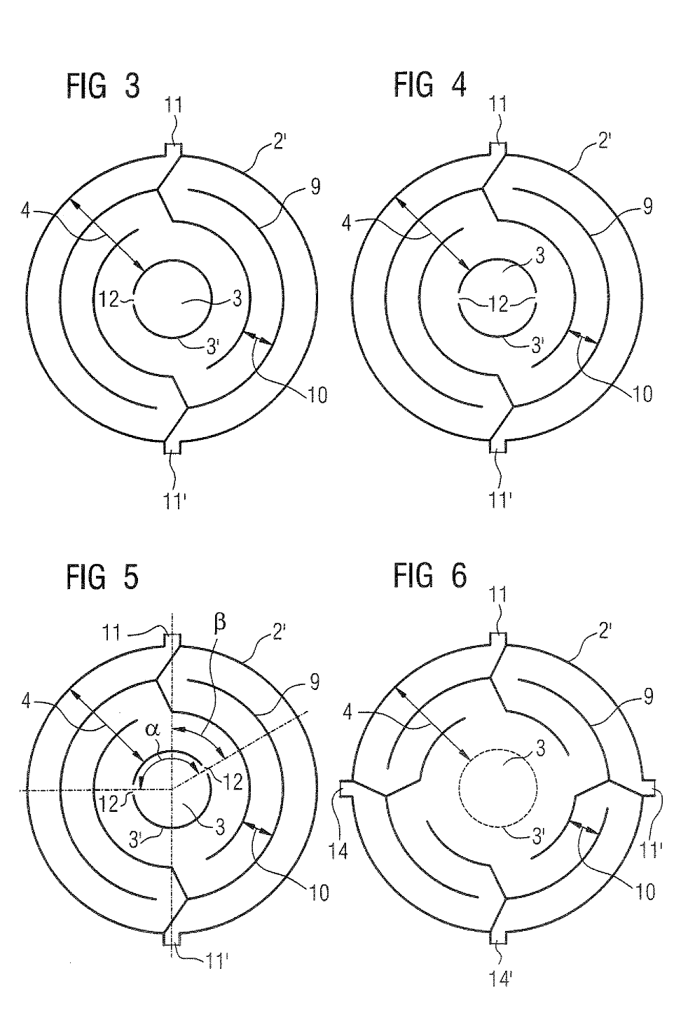

In the plan view of FIG. 3 a further embodiment of an emitter plate 2 of a surface emitter 1 is shown. Slits 9 are introduced into the emitter plate 2 such that a serpentine current path 10 is generated between the two heating current connections 11, 11′. These current paths proceed only in a region 4 of the emitter plate 2 that adjoins the central region 3. The central region 3 is connected with the adjoining region 4 only via a connection web 12. If a heating current is applied to both heating current connections 11, 11′, the heating voltage drop along the current path 10 heats only the adjoining region 4 to cause it to emit electrons. Heating current does not flow through the central region 3. The central region 3 is heated only by heat conduction from the adjoining region 4 through the narrow connection webs 12. The central region 3 therefore emits no electrons, or nearly no electrons.

The emitter plate 2 exhibits an outer contour 2′ that is circular. The central region 3 of the emitter plate 2 likewise exhibits a circular outer contour 3′. Only the region 4 (which is fashioned in the manner of a washer) adjoining the central region 3 thus emits electrons. Since no electrons are emitted in the central region 3, this leads to a lower expansion of the electron beam (as illustrated in the explanation regarding FIG. 2) since the electrons repel each other less strongly. The electron beam thus can be focused better in comparison to an electron beam emitted from a conventional surface emitter. Since the electron beam additionally exhibits a rotationally symmetrical geometry, a surface emitter I with such an emitter plate 2 is suitable for rotary piston radiators.

FIG. 4 shows a further variant of an emitter plate 2 for a surface emitter 1. The single difference from the emitter plate 2 shown in FIG. 3 is that the central region 3 is connected with the adjoining region 4 via two opposing connection webs 12. The two connection webs 12 are at the same potential given a heating current applied to the emitter plate. At maximum, a very small heating current therefore flows transversely across the central region 3 when the connection webs are executed sufficiently wide. A heating of the central region therefore likewise occurs exclusively or almost exclusively via heat conduction through the two connection webs 12. The two connection webs 12 lead to an increased mechanical stability of the emitter plate.

FIG. 5 shows an emitter plate of a surface emitter 1 in which, as in FIG. 4, the central region 3 is likewise connected with the adjoining region 4 via two connection webs 12, but the two connection webs 12 are not at the same potential, meaning that the angle a between the two connection webs 12 exhibits a value differing from 180°. The position of the both connection webs 12 is unambiguously determined by means of the angle β between the perpendicular bisector of the side and one of the two connection webs 12. Given application of a heating current at the two heating current connections 11, 11′, a potential difference exists between the two connection webs 12. The magnitude of this potential difference (and thus the magnitude of the heating current flowing between the two connection webs) can be adjusted by selection of the angle between the connection webs 12. The electron density distribution for the central region thus can be set within a very broad range by the selection of the angle between the two connection webs 13. In contrast to the embodiments for the emitter plate 2 described in FIG. 3 and FIG. 4, with regard to the electron density distribution there is no steep decline between the adjoining region 4 and the central region 3 but rather a sliding transition. A further improvement of the electron density distribution at the anode location can be achieved with the focusing of the electron beam.

FIG. 6 shows an emitter plate 2 of a surface emitter 1 has heating current connections 11, 11′ for a first heating current circuit and heating current connections 14, 14′ for a second heating current circuit. The connections 11, 11′, 14, 14′ are respectively arranged offset in pairs by 90°. The arrangement of the slits 9 for generation of the current paths 10 on the emitter plate 2 is executed such that heating currents respectively flow between the heating current connections 11, 11′ and between the heating current connections 14, 14′. Since the current paths are executed symmetrically in this case, no heating current or nearly no heating current flows in the central region 3 of the emitter plate 2. The electron density distribution of the electrons emitted from the central region 3 is variable in a very broad range by a suitable arrangement of the current paths 10 as well as the heating currents flowing between the heating current connections 11, 11′ and 14, 14′. The initially higher expenditure to provide two pairs of heating current connections 11, 11′, 14, 14′ as well as the associated heating current circuits provides the advantage of allowing a specification of the electron density distribution, which allows the electron density distribution to be optimized to the focal spot at the anode. The outer contour 3′ of the central region 3 is shown dashed in order to indicate that it can be adjustably (selectively) set. This embodiment enables the electron density to be adjusted solely by suitable control of the heating current connections 11, 11′ and 14, 14′. A further advantage of the arrangement shown in FIG. 6 is that the emitter plate 2 exhibits a higher mechanical stability than in the variants shown in FIG. 3 through FIG. 5 with one or two connection webs 12.

All emitter plates 2 in FIG. 3 through 6 additionally exhibit the advantage that ions that are kicked out at the anode and strike on the emitter plate 2, in the central region 3 barely influence the electron density distribution of the emitter plate 2, since the central region 4 is of subordinate importance for the electron density distribution.

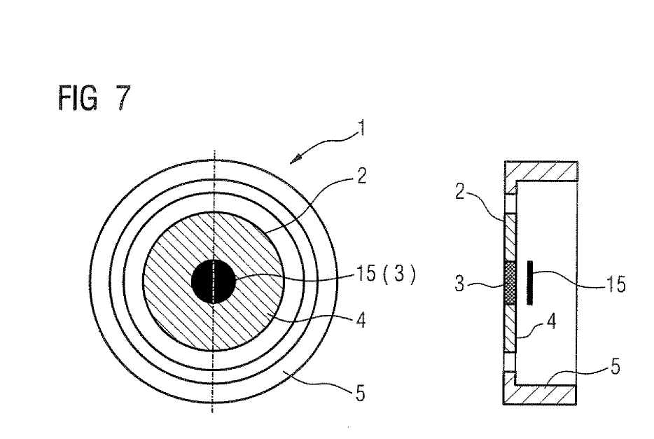

FIG. 7 shows in plan view and a section through a surface emitter 1 with an emitter plate 2 having a diaphragm plate 15 with a circular outer contour 15′ located in front of the central region 3. The focusing element 5 exhibits the same geometric properties as described herein regarding FIG. 1 and FIG. 2. The use of a conventional emitter plate 2 is possible due to the diaphragm plate 15 arranged in front of the emitter plate 2. Electrons exiting from the central region 3 of this emitter plate 2 strike on the diaphragm plate 15 and are not accelerated in the direction toward the anode. The diaphragm plate 15 additionally serves as protection from ions produced from the anode that are accelerated in the direction of the emitter plate 2. These ions strike the diaphragm plate 15 and thus can cause no mechanical damage to the emitter plate 2. The variant with the diaphragm plate 15 placed in front leads to an electron density distribution comparable to the variants for the emitter plate 2 described in FIG. 3 and FIG. 4. This is a particularly simple and cost-effective variant.

Although modifications and changes may be suggested by those skilled in the art, it is the intention of the inventors to embody within the patent warranted hereon all changes and modifications as reasonably and properly come within the scope of their contribution to the art.

We claim as our invention:

1. A thermionic flat electron emitter comprising:
an emitter plate having slits therein that form serpentine current paths in said emitter plate; and
a structure that, when current flows in said current paths, causes an electron density of emitted electrons to be lower in a central region of the emitted plate than in a surrounding region of the emitter plate adjoining the central region.

2. A thermionic flat electron emitter as claimed in claim 1 wherein said structure comprises an arrangement of said slits in said emitter plate.

3. A thermionic flat electron emitter as claimed in claim 2 comprising a single connection web mechanically and electrically connecting said central region of said emitter plate with said surrounding region of said emitter plate.

4. A thermionic flat electron emitter as claimed in claim 2 comprising two, oppositely disposed connection webs mechanically and electrically connecting said central region of said emitter plate with said surrounding region of said emitter plate, said connection webs being disposed at respective positions to cause said connection webs to be at a same potential when said currents flow in said current paths.

5. A thermionic flat electron emitter as claimed in claim 2 comprising two connection webs, offset from each other by a non-1800 angle, that mechanically and electrically connect said central region of said emitter plate with said surrounding region of said emitter plate, said two connection webs, due to being offset by said non-180° angle, having a potential different therebetween, dependent on said non-180° angle, when said currents flow in said current paths.

6. A thermionic fiat electron emitter as claimed in claim 1 wherein said structure comprises at least two circuits connected to the respective current paths.

7. A thermionic flat electron emitter as claimed in claim 6 comprising two circuits respectively connected to two current paths in said emitter plate, said two circuits being respectively connected to said current paths by connection pairs that are offset from each other by 90°.

8. A thermionic flat electron emitter as claimed in claim 1 wherein said central region has a rotationally symmetrical outer contour.

9. A thermionic flat electron emitter as claimed in claim 8 wherein said central region has a substantially circular outer contour.

10. A thermionic flat electron emitter as claimed in claim 1 wherein said structure comprises a diaphragm plate spaced from and disposed in front of said central region at a side of said emitter plate at which the electrons are emitted.

11. A thermionic fiat electron emitter as claimed in claim 10 wherein said diaphragm plate has a substantially rotationally symmetrical outer contour.

12. A thermionic flat electron emitter as claimed in claim 11 wherein said diaphragm plate has a substantially circular outer contour.

13. A thermionic flat electron emitter as claimed in claim 1 wherein said emitter plate has a substantially rotationally symmetrical outer contour.

14. A thermionic flat electron emitter as claimed in claim 13 wherein said emitter plate has a substantially circular outer contour.

15. An x-ray tube comprising:
an evacuated housing;
an anode contained in said evacuated housing; and
a thermionic flat electron emitter contained in said housing comprising an emitter plate having slits therein that form serpentine current paths in said emitter plate, and a structure that, when current flows in said current paths, causes an electron density of emitted electrons to be lower in a central region of the emitted plate than in a surrounding region of the emitter plate adjoining the central region.
